(19) United States
(12) Patent Application Publication
(10) Pub. No.: US 2023/0244145 A1
(43) Pub. Date: Aug. 3, 2023

(54) SILICON-CONTAINING MONOMER MIXTURE, POLYSILOXANE, RESIN COMPOSITION, PHOTOSENSITIVE RESIN COMPOSITION, CURED FILM, PRODUCTION METHOD FOR CURED FILM, PATTERNED CURED FILM, AND PRODUCTION METHOD FOR PATTERNED CURED FILM

(71) Applicant: CENTRAL GLASS COMPANY, LIMITED, Yamaguchi (JP)

(72) Inventors: Takashi MASUBUCHI, Saitama (JP); Tomohiro KATAMURA, Saitama (JP); Kazuhiro YAMANAKA, Saitama (JP)

(21) Appl. No.: 18/184,354

(22) Filed: Mar. 15, 2023

Related U.S. Application Data
(63) Continuation of application No. PCT/JP2021/032337, filed on Sep. 2, 2021.

(30) Foreign Application Priority Data
Sep. 16, 2020 (JP) 2020-155706

(51) Int. Cl. G03F 7/075; C08L 83/06; C08J 3/24

(52) U.S. Cl. CPC G03F 7/0757; C08J 3/247; C08L 83/06; C08L 2201/10; C08L 2203/16; C08L 2203/206

(57) ABSTRACT

A polysiloxane that has a fast polymerization reaction rate and good storage stability is provided. Alternatively, a silicon-containing monomer mixture as a raw material of the polysiloxane, a resin composition, a photosensitive resin composition, a cured film, or a patterned cured film containing the polysiloxane are provided. Alternatively, the present invention provides a production method for a resin composition, a photosensitive resin composition, a cured film, or a patterned cured film containing the polysiloxane. A mixture is provided including a first monomer containing silicon represented by the following general formula (X); and a second monomer containing silicon represented by the following general formula (Y). In the case where A is set to a contained amount of the first monomer containing silicon and B is set to a contained amount of the second monomer containing silicon, the following relationship is satisfied.

$$\text{B} / \left(\text{A + B}\right) \text{>} \text{0} \text{.04}$$

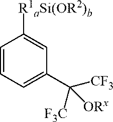

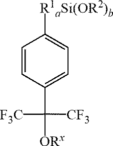

### CROSS-REFERENCE TO RELATED APPLICATIONS

This application is a Continuation of International Patent Application No. PCT/JP2021/032337, filed on Sep. 2, 2021, which claims the benefit of priority to Japanese Patent Application No. 2020-155706, filed on Sep. 16, 2020, the entire contents of which are incorporated herein by reference.

### FIELD

The present invention relates to a silicon-containing monomer mixture, a resin composition containing a polymer compound containing siloxane bonds, a photosensitive resin composition, a cured film, a patterned cured film, which can be used as various optical devices, photosensitive materials, sealing materials, and the like, and a production method for the same.

### BACKGROUND

Polymer compounds containing siloxane bonds (hereinafter also referred to as polysiloxane) are used as coating materials for liquid crystal displays and organic EL displays, coating materials for image sensors, and sealing materials in the field of semiconductors, taking advantage of their high heat resistance, transparency, and the like. In addition, a polysiloxane is also used as a hard mask material for multilayer resists because of its high resistance to oxygen plasma. In order to use the polysiloxane as a patternable photosensitive material, it is required that the polysiloxane be soluble in an alkaline aqueous solution such as an alkaline developer. A means for making the polysiloxane soluble in the alkali developer includes the use of a silanol group in the polysiloxane or the introduction of an acidic group into the polysiloxane. Examples of such an acidic group include a phenol group, a carboxyl group, and a fluorocarbinol group.

Japanese laid-open patent publication No. 2012-242600 discloses a polysiloxane using a silanol group as a soluble group in an alkali developer. On the other hand, a polysiloxane having a phenol group is disclosed in Japanese laid-open patent publication No. H4-130324. A polysiloxane having a carboxyl group is disclosed in Japanese laid-open patent publication No. 2005-330488. In addition, a polysiloxane containing a hexafluoroisopropanol group (2-hydroxy-1,1,1,3,3,3-hexafluoroisopropyl group [—C(CF₃)₂OH]) is disclosed in Japanese laid-open patent publication No. 2015-129908. These polysiloxanes are used as positive resist compositions in combination with a photoacid generator or a photosensitive compound having a quinone diazide group.

The polysiloxane having a hexafluoroisopropanol group (2-hydroxy-1,1,1,3,3,3-hexafluoroisopropyl group [—C(CF₃)₂OH)]) disclosed in Japanese laid-open patent publication No. 2015-129908 and Japanese laid-open patent publication No. 2014-156461 relating to a positive resist composition has good transparency, heat resistance, and acid resistance. For this reason, a pattern structure based on the polysiloxane is promising as a permanent structure in various elements.

### SUMMARY

In an embodiment, a polysiloxane that has a fast polymerization reaction rate and good storage stability is provided. Alternatively, a silicon-containing monomer mixture as a raw material of the polysiloxane, a resin composition, a photosensitive resin composition, a cured film, or a patterned cured film containing the polysiloxane are provided. Alternatively, the present invention provides a production method for a resin composition, a photosensitive resin composition, a cured film, or a patterned cured film containing the polysiloxane.

As a result of intensive studies to solve the above problems, a silicon-containing monomer mixture was found that includes:
a first monomer containing silicon represented by the following general formula (X); and
a second monomer containing silicon represented by the following general formula (Y),

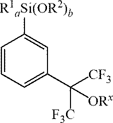

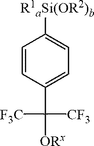

wherein, in the general formula (X), in the case where there are a plurality of R¹, R¹ are independently selected from a group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms and a phenyl group. All of the hydrogen atoms of the alkyl group, the alkenyl group or the phenyl group may be substituted or not substituted by fluorine atoms, or a part of the hydrogen atoms of the alkyl group, the alkenyl group or the phenyl group may be substituted by fluorine atoms,
in the case where there are a plurality of R², R² are independently a group consisting of a linear alkyl group having 1 to 5 carbon atoms or a branched alkyl group having 3 to 5 carbon atoms, all of the hydrogen the of the alkyl group may be substituted or not substituted by fluorine atoms, or a part of the hydrogen atoms of the alkyl group may be substituted by fluorine atoms,
R^{x} is a hydrogen atom or an acid-labile group, a is an integer of 0 to 2, b is an integer of 1 to 3, a + b = 3,
in the general formula (Y), R¹, R², R^{x}, a and b are defined the same as in the general formula (X),
A is set to a contained amount of the first monomer containing silicon, B is set to a contained amount of the second monomer containing silicon, and
the following relationship is satisfied in a mole ratio.
$$\text{B} / \left(\text{A} + \text{B}\right) > 0.04$$

There is provided a polysiloxane including:
a structural unit (1) represented by the following general formula (1); and
a structural unit (2) represented by the following general formula (2),

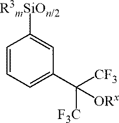

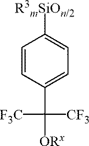

wherein, in the general formula (1), in the case where there are a plurality of R³, R³ are independently selected from a group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms, a phenyl group, hydroxy group, a linear alkoxy group having 1 to 5 carbon atoms, and a branched alkoxy group having 3 to 5 carbon atoms. All of the hydrogen atoms of the alkyl group, the alkenyl group, the phenyl group or alkoxy group may be substituted or not substituted by fluorine atoms, or a part of the hydrogen atoms of the alkyl group, the alkenyl group, the phenyl group or alkoxy group may be substituted by fluorine atoms,
R^{x} is a hydrogen atom or an acid-labile group,
m is a number of 0 or more and less than 3, n is a number of more than 0 and 3 or less, m + n = 3,
in the general formula (2), R³, R^{x}, m and n are defined the same as in the general formula (1).

In addition, there is provided a production method for a patterned cured film including:
a step of a film formation applying a photosensitive resin composition on a substrate to form a photosensitive resin film;
a step of exposing the photosensitive resin film;
a step of developing the photosensitive resin film after exposing to form a pattered resin film; and
a step of curing by heating the pattered resin film to convert the pattered resin film to the patterned cured film,
wherein the photosensitive resin composition includes:
   the above-described polysiloxane as a component (A);
   at least one photosensitizing agents selected from a group consisting of a quinone diazide compound, a photoacid generator, a photobase generator and photo-radical generator as a component (B); and
   a solvent as a component (C).

### BRIEF DESCRIPTION OF DRAWINGS

FIG. 1 is a schematic view illustrating a production method for a patterned cured film 111 according to an embodiment of the present invention.

FIG. 2 is a diagram showing a relationship between a reaction time and a weight-average molecular weight of a polysiloxane according to an example of the present invention.

FIG. 3 is a diagram showing a relationship between a storage time and a weight-average molecular weight of a polysiloxane according to an example of the present invention.

### DESCRIPTION OF EMBODIMENTS

Hereinafter, a polysiloxane for an optical member according to an embodiment of the present invention, a silicon-containing monomer mixture (hereinafter, sometimes simply referred to as a “mixture”) as a raw material of the polysiloxane, a resin composition, a photosensitive resin composition, a cured film, and a patterned cured film containing the polysiloxane, and a production method for the same will be described. However, the embodiments of the present invention are not to be construed as being limited to the descriptions of the embodiments and examples described below. In addition, in the present specification, the expression “X to Y” in the description of a numerical range represents X or more and Y or less unless otherwise specified.

After the silicon-containing monomer as a raw material is polymerized to obtain a polysiloxane, the conventional polysiloxane is usually stored under refrigeration. The faster the polymerization reaction rate, the higher the production efficiency can be improved. However, according to studies conducted by the present inventors, it has been clarified that when the polymerization reaction rate of the silicon-containing monomer is high, the stability of the obtained polysiloxane at the time of storage may become insufficient even under refrigeration.

In the expression of the group (atomic group) in the present specification, the expression which does not indicate whether it is substituted or unsubstituted includes both those having no substituent and those having a substituent. For example, the “alkyl group” includes not only an alkyl group having no substituent (unsubstituted alkyl group) but also an alkyl group having a substituent (substituted alkyl group).

In the present specification, a “cyclic alkyl group” includes not only a monocyclic structure but also a polycyclic structure. The same applies to the “cycloalkyl group”.

The expression “(meth)acryl” in the present specification represents a concept including both acryl and methacryl. The same applies to similar expressions such as “(meth)acrylate”.

The term “organic group” in the present specification means an atomic group obtained by removing one or more hydrogen atoms from an organic compound, unless otherwise specified. For example, a “monovalent organic group” refers to an atomic group obtained by removing one hydrogen atom from any organic compound.

In the present specification, a hexafluoroisopropanol group represented by —C(CF₃)₂OH is sometimes referred to as an “HFIP group”.

### 1: Mixture

Hereinafter, a mixture which is one of the embodiments will be described. The mixture according to the present embodiment includes a silicon-containing monomer represented by the following formula (X) and a silicon-containing monomer represented by the following formula (Y). In the case where the content of the silicon-containing monomer represented by the general formula (X) contained in the mixture according to the present embodiment is set to A and the content of the silicon-containing monomer represented by the general formula (Y) is set to B, the mixture according to the present embodiment satisfies B / (A + B) > 0.04 in the mole ratio.

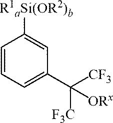

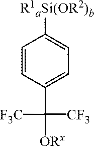

Mixing an appropriate amount of a silicon-containing monomer (Y) with a silicon-containing monomer (X) makes it possible to improve the reaction rate of the polymerization reaction of the mixture according to the present embodiment. The silicon-containing monomer (X) has a bulky HFIP group at the meta-position, and the silicon-containing monomer (Y) has a bulky HFIP group at the para-position. Among these, in the silicon-containing monomer (Y), since the HFIP group is present at a para position farther from a silicon atom, it is presumed that the silicon atom is susceptible to nucleophilic attack by nucleophiles, and a hydrolysis reaction or a polycondensation reaction (formation of siloxane bonds by dehydration) can easily occur.

Therefore, the value of B / (A + B) may be preferably 0.05 or more, more preferably 0.1 or more. In addition, the upper limit value of the mixture is not particularly limited, but may be, for example, 0.95 or less. Further, for the purpose of obtaining good storage stability of the polysiloxane described later, it is preferably 0.9 or less.

In the silicon-containing monomer (X), in the case where there is a plurality of R¹, each R¹ is independently selected from a group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms, and a phenyl group. In addition, all of the hydrogen atoms of the alkyl group, the alkenyl group, or the phenyl group may or may not be substituted by fluorine atoms. Alternatively, a part of the hydrogen atoms of the alkyl group, the alkenyl group, or the phenyl group may be substituted by fluorine atoms.

In the case where there is a plurality of R², each R² is independently a linear alkyl group having 1 to 5 carbon atoms or a branched alkyl group having 3 to 5 carbon atoms. In addition, all of the hydrogen atoms of the alkyl group may or may not be substituted by fluorine atoms. Alternatively, a part of the hydrogen atoms of the alkyl group may be substituted by fluorine atoms.

R^{x} is a hydrogen atom or an acid-labile group. a is an integer of 0 to 2, b is an integer of 1 to 3, and satisfies the following relationship.

$$\text{a} + \text{b} = 3$$

Examples of the acid-labile group include an alkoxycarbonyl group, an acetal group, a silyl group, and an acyl group.

Examples of the alkoxycarbonyl group include a tert-butoxycarbonyl group, a tert-amyloxycarbonyl group, a methoxycarbonyl group, an ethoxycarbonyl group, and an i-propoxycarbonyl group.

Examples of the acetal group include a methoxymethyl group, an ethoxyethyl group, a butoxyethyl group, a cyclohexyloxyethyl group, a benzyloxyethyl group, a phenethyloxyethyl group, an ethoxypropyl group, a benzyloxypropyl group, a phenethyloxypropyl group, an ethoxybutyl group, and an ethoxyisobutyl group. In addition, an acetal group in which vinyl ether is added to a hydroxyl group can also be used.

Examples of the silyl group include a trimethylsilyl group, an ethyldimethylsilyl group, a triethylsilyl group, an i-propyldimethylsilyl group, a methyldi-i-propylsilyl group, a tri-i-propylsilyl group, a t-butyldimethylsilyl group, a methyldi-t-butylsilyl group, a tri-t-butylsilyl group, a phenyldimethylsilyl group, a methyldiphenylsilyl group, and a triphenylsilyl group.

Examples of the acyl group include an acetyl group, a propionyl group, a butyryl group, a heptanoyl group, a hexanoyl group, a valeryl group, a pivaloyl group, an isovaleryl group, a lauroyl group, a myristoyl group, a palmitoyl group, a stearoyl group, an oxalyl group, a malonyl group, a succinyl group, a glutaryl group, an adipoyl group, a pimeloyl group, a suberoyl group, an azelaoyl group, a sebacoyl group, an acryloyl group, a propioloyl group, a methacryloyl group, a crotonoyl group, an oleoyl group, a maleoyl group, a fumaroyl group, a mesaconoyl group, a camphoroyl group, a benzoyl group,. a phthaloyl group, an isophthaloyl group, a terephthaloyl group, a naphthoyl group, a taloyl group, a hydroatropoyl group, an atropoyl group, a cinnamoyl group, a furoyl group, a tenoyl group, a nicotinoyl group, and an isonicotinoyl group.

Furthermore, it is also possible to use these acid-labile groups in which some or all of the hydrogen atoms are substituted by fluorine atoms.

In the silicon-containing monomer (Y), the definitions of R¹, R², R^{x}, a, and b are the same as the definitions of R¹, R², R^{x}, a, and b in the general formula (X).

The production method for the silicon-containing monomer (X) is not particularly limited. Atypical production method is described below.

A compound represented by the general formula (X) is known, and for example, the compound represented by the general formula (X) can be synthesized with reference to the method described in Japanese laid-open patent publication No. 2014-156461.

Next, a compound represented by the general formula (Y) is known, and for example, the compound represented by the general formula (Y) can be synthesized with reference to the method described in Japanese laid-open patent publication No. 2014-156461.

In an embodiment, the mixture may contain a solvent or the like.

The solvent is not particularly limited as long as it does not react with the compound represented by the general formula (X) and the compound represented by the general formula (Y), and examples thereof include hydrocarbon solvents such as pentane, hexane, heptane, octane, and toluene, ether solvents such as tetrahydrofuran, diethyl ether, dibutyl ether, diisopropyl ether, methyl tertiary butyl ether, 1,2-dimethoxyethane, 1,4-dioxane, and propylene glycol monomethyl ether, alcohol solvents such as methanol, ethanol, 1-propanol, isopropanol, and 1-butanol, ester solvents such as ethyl acetate, methyl acetate, butyl acetate, and propylene glycol monomethyl ether acetate, ketone solvents such as acetone, methyl ethyl ketone, methyl tertiary butyl ketone, and cyclohexanone, chlorine solvents such as dichloromethane and chloroform, and fluorine-based solvents such as Novec 7200, Novec 7000, Novec 7100, and Novec 7300 (manufactured by 3M Japan Limited) can be used. These solvents may be used alone or in a mixture.

### 2: Polysiloxane

Hereinafter, a polysiloxane of the present embodiment will be described. The polysiloxane according to the present embodiment contains a structural unit (1) represented by the following general formula (1) and a structural unit (2) represented by the following general formula (2).

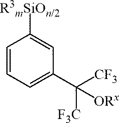

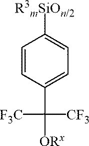

In an embodiment, the polysiloxane may be a copolymer polysiloxane containing both the structural unit (1) and the structural unit (2).

The copolymer polysiloxane according to the present embodiment is obtained by hydrolyzing a portion of “OR²” in the general formula (X) and a portion of “OR²” in the general formula (Y) to form a silanol group by using the above-described silicon-containing monomer mixture under an acidic catalyst or a basic catalyst, and dehydrating and condensing two or more of the silanol groups. Alternatively, the copolymer polysiloxane according to the present embodiment can also be obtained by a condensation reaction between the generated silanol group and a portion of “Si—OR²”. In addition to using the above-described silicon-containing monomer mixture, the copolymer polysiloxane according to the present embodiment can be obtained from halosilane in which the portion of “OR²” in the general formula (X) and the portion of “OR²” in the general formula (Y) are changed to halogen elements in the same reaction. Similarly, the copolymer polysiloxane according to the present embodiment can be obtained in the case where a mixture of alkoxysilane and halosilane is used.

In addition, when hydrolyzing and polycondensing the silicon-containing monomer mixture, the silicon-containing monomer mixture may be provided in a solution diluted with a solvent. For example, Japanese laid-open patent publication No. 2013-224279 describes that when a predetermined silicon-containing compound for forming a resist underlayer film is obtained by hydrolytic condensation, a monomer as a raw material thereof can be diluted with an organic solvent. The solvent that can be used for dilution in the present invention is not particularly limited, but is preferably the same as “the solvent that may be contained in the mixture of the present invention” described above.

As described in “1: Mixture” above, it is presumed that in the silicon-containing monomer (Y), since the HFIP group is present at the para-position, the polymerization reaction rate is improved. Even after the polysiloxane is formed using the silicon-containing monomer (Y), the HFIP group at the para-position is contained as the structural unit (2). According to studies conducted by the present inventors, it has been found that a polysiloxane using only the silicon-containing monomer (Y) as a monomer of a material at the time of producing a polysiloxane tends to have low stability when stored under refrigeration. In addition, it has been clarified that when the polysiloxane containing the structural unit (2) contains the structural unit (1) in which the HFIP group is present at the meta-position, a decrease in storage stability is suppressed. It is thought that since the HFIP group contained in the structural unit (1) is present at the meta-position, the steric hindrance is greater than that of the para-form, which suppresses the condensation between the silanols during storage and prevents the weight-average molecular weight (Mw) from increasing.

The polysiloxane according to the present embodiment may contain the structural unit (1), and the content thereof is not particularly limited. For example, when the existence ratio of the structural unit (1) in the polysiloxane is set to (Aa) and the existence ratio of the structural unit (2) in the polysiloxane is set to (Bb), Bb / (Aa + Bb) may be 0.95 or less in the mole ratio in the polysiloxane according to the present embodiment. In addition, 0.9 or less is preferable because the storage stability is further improved.

In addition, as described above, since the polymerization rate when obtaining the polysiloxane is good, the existence ratio (Aa) of the structural unit (1) and the existence ratio (Bb) of the structural unit (2) may satisfy Bb/ (Aa + Bb) > 0.04 in the mole ratio. Bb / (Aa + Bb) ≥ 0.05 is preferred.

In the structural unit (1), in the case where there is a plurality of R³, each R³ is independently selected from the group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms, a phenyl group, a hydroxy group, a linear alkoxy group having 1 to 5 carbon atoms, and a branched alkoxy group having 3 to 5 carbon atoms. All of the hydrogen atoms of the alkyl group, the alkenyl group, the phenyl group, and the alkoxy group may or may not be substituted by fluorine atoms. Alternatively, a part of the hydrogen atoms of the alkyl group, the alkenyl group, the phenyl group, and the alkoxy group may be substituted by fluorine atoms.

R^{x} is a hydrogen atom or an acid-labile group. m is a number 0 or more and less than 3, n is a number more than 0 and 3 or less, and satisfies m + n = 3. In addition, the acid-labile group described above can be used as the acid-labile group.

In the structural unit (2), the definitions of R³, R^{x}, m, and n are the same as the definitions of R³, R^{x}, m, and n described in the structural unit (1).

In addition, O_{n/2} in the structural unit (1) and the structural unit (2) is commonly used as a representation of a polysiloxane compound. The following formula (1-1) represents the case where n is 1. The formula (1-2) represents the case where n is 2. The formula (1-3) represents the case where n is 3. In the case where n is 1, the structural unit (1) and the structural unit (2) are located at the end of a polysiloxane chain in the polysiloxane.

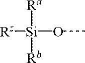

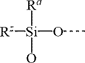

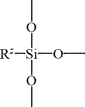

In the general formulas (1-1) to (1-3), R^{z} is the following formula (R^{z} - 1) or formula (R^{z} - 2).

R^{a} and R^{b} each independently have the same meaning as the R³ in the general formula (1). The broken line represents a bond to Si atom.

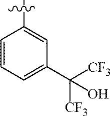

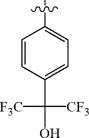

The broken line represents a bond to Si atom.

When the polycondensation is performed, a silicon-containing monomer different from the silicon-containing monomer (X) or the silicon-containing monomer (Y) may be present in the reaction system. As a result, a copolymer containing three or more components can be obtained. The copolymer containing three or more components will be further described.

In an embodiment, the polysiloxane may further contain at least one of a structural unit (3) represented by the following general formula (3) and a structural unit (4) represented by the following general formula (4).

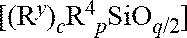

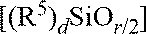

In the general formula (3), R^{y} is a monovalent organic group having 1 to 30 carbon atoms containing any of an epoxy group, an oxetane group, an acryloyl group, a methacryloyl group, or a lactone group.

In the general formula (3), R⁴ represents a hydrogen atom, a halogen element, an alkyl group having 1 or more and 3 or less carbon atoms, a phenyl group, a hydroxyl group, an alkoxy group having 1 or more and 5 or less carbon atoms, or a fluoroalkyl group having 1 or more and 3 or less carbon atoms.

c is a number 1 or more and 3 or less, p is a number 0 or more and less than 3, and q is a number more than 0 and 3 or less, and satisfies c + p + q = 4.

In this case, in the structural unit (3) represented by the general formula (3), c, p, and q are as follows, c is an integer of 1 to 3, p is an integer of 0 to 3, and q is an integer of 0 to 3 as theoretical values. In addition, c + p + q = 4 means that the sum of the theoretical values is 4. However, for example, in the value obtained by a ²⁹Si NMR measurement, c, p, and q are obtained as average values, respectively, so that c of the average value is a decimal rounded to 1 or more and 3 or less, p is a decimal rounded to 0 or more and 3 or less (but p < 3.0), and q is a decimal rounded to 0 or more and 3 or less (but q ≠ 0).

In the case where there is a plurality of R^{y} or R⁴, any of the above-described substituents is independently selected as R^{y} or R⁴.

In the general formula (4), R⁵ is a substituent selected from a group consisting of a halogen group, an alkoxy group, and a hydroxy group.

d is a number 0 or more and less than 4, r is a number more than 0 and 4 or less, and satisfy d + r = 4.

In addition, in the structural unit (4) represented by the general formula (4), as theoretical values, d is an integer of 0 to 4, and r is an integer of 0 to 4. In addition, d + r = 4 means that the sum of the theoretical values is 4. However, for example, in the value obtained by the ²⁹Si NMR measurement, since d and r are obtained as the average values, the d of the average value may be a decimal rounded to 0 or more and 4 or less (but d < 4.0), and the r may be a decimal rounded to 0 or more and 4 or less (but r ≠ 0).

In an embodiment, the monovalent organic group R^{y} may be a group represented by the following general formulas (2a), (2b), (2c), (3a), or (4a) in the polysiloxane.

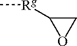

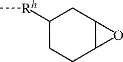

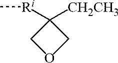

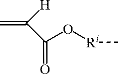

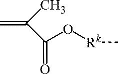

In the general formulas (2a), (2b), (2c), (3a), or (4a), R^{g}, R^{h}, Rⁱ, R^{j}, and R^{k} each independently represents a linking group or a divalent organic group. In addition, the broken line represents a bond.

In this case, in the case where R^{g}, R^{h}, and Rⁱ are divalent organic groups, the divalent organic group may include, for example, an alkylene group having 1 to 20 carbon atoms, and may include one or more sites forming an ether bond. In the case where the number of carbon atoms is three or more, the alkylene group may be branched, or separated carbons may be connected to form a ring. In the case where the alkylene group is two or more, oxygen may be inserted between carbons to contain one or more sites forming an ether bond, and these are preferred examples as the divalent organic group.

In the structural unit (3), in the case where the R^{y} is represented by the general formulas (2a), (2b), and (2c), particularly preferred alkoxysilane as a raw material may include 3-glycidoxypropyltrimethoxysilane (manufactured by Shin-Etsu Chemical Co., Ltd., product name: KBM-403), 3-glycidoxypropyltriethoxysilane (manufactured by Shin-Etsu Chemical Co., Ltd., product name: KBE-403), 3-glycidoxypropylmethyldiethoxysilane (manufactured by Shin-Etsu Chemical Co., Ltd., product name : KBE-402), 3-glycidoxypropylmethyldimethoxysilane (manufactured by Shin-Etsu Chemical Co., Ltd., product name: KBM-402), 2-(3,4-epoxycyclohexyl)ethyltrimethoxysilane (manufactured by Shin-Etsu Chemical Co., Ltd., product name: KBM-303), 2-(3,4-epoxycyclohexyl)ethyltriethoxysilane, 8-glycidoxyoctyltrimethoxysilane (manufactured by Shin-Etsu Chemical Co., Ltd., product name: KBM-4803), [(3-ethyl-3-oxetanyl)methoxy]propyltrimethoxysilane, and [(3-ethyl-3-oxetanyl)methoxy]propyltriethoxysilane.

In the general formula (3a) or (4a), preferred examples in the case where R^{j} and R^{k} are divalent organic groups include those listed as preferred groups in R^{g}, R^{h}, Rⁱ, R^{j}, and R^{k}.

In the structural unit (3), in the case where the R^{y} is represented by the general formulas (3a) and (4a), particularly preferred alkoxysilane as a raw material may include 3-methacryloxypropyltrimethoxysilane (manufactured by Shin-Etsu Chemical Co., Ltd., product name: KBM-503), 3-methacryloxypropyltriethoxysilane (manufactured by Shin-Etsu Chemical Co., Ltd., product name: KBE-503), 3-methacryloxypropylmethyldimethoxysilane (manufactured by Shin-Etsu Chemical Co., Ltd., product name: KBM-502), 3-methacryloxypropylmethyldiethoxysilane (manufactured by Shin-Etsu Chemical Co., Ltd., product name: KBE-502), 3-acryloxypropyltrimethoxysilane (manufactured by Shin-Etsu Chemical Co., Ltd., product name: KBM-5103), and 8-methacryloxyoctyltrimethoxysilane (manufactured by Shin-Etsu Chemical Co., Ltd., product name: KBM-5803).

In the case where the R^{y} group includes a lactone group, if the R^{y} group is represented by a R^{y}—Si structure, the R^{y} group is preferably a group selected from the following formulas (5-1) to (5-20), formulas (6-1) to (6-7), formulas (7-1) to (7-28), and formulas (8-1) to (8-12).

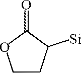

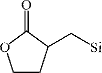

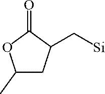

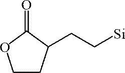

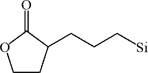

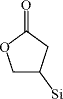

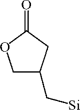

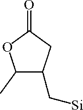

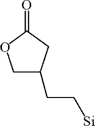

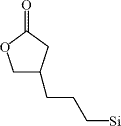

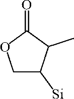

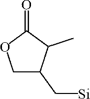

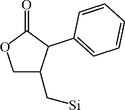

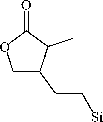

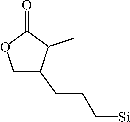

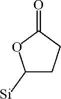

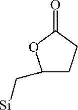

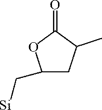

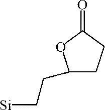

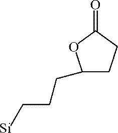

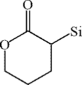

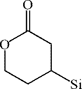

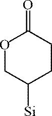

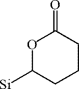

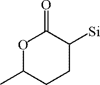

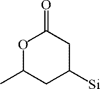

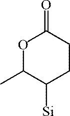

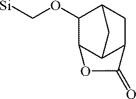

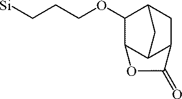

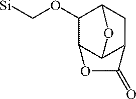

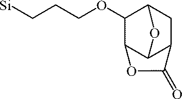

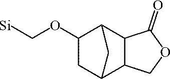

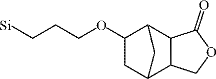

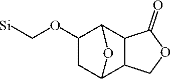

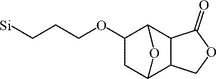

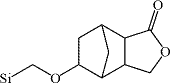

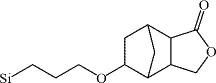

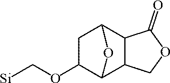

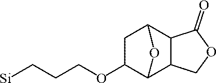

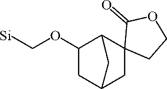

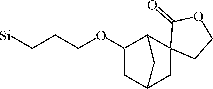

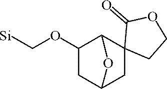

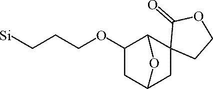

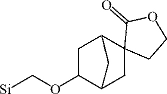

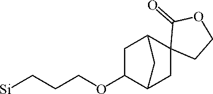

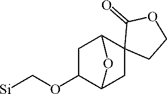

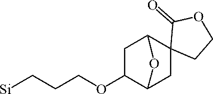

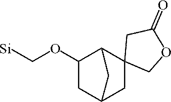

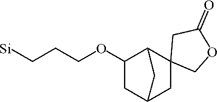

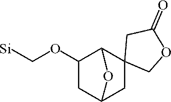

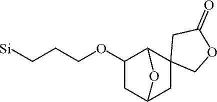

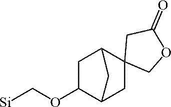

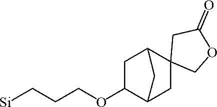

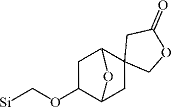

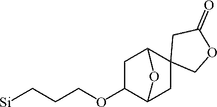

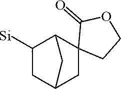

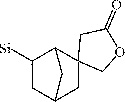

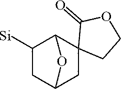

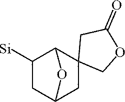

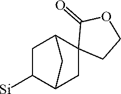

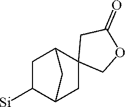

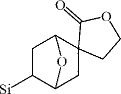

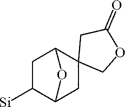

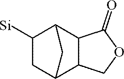

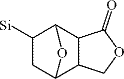

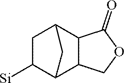

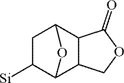

For O_{q/2} in the general formula (3), the following general formula (2-1) represents the case where q is 1, the general formula (2-2) represents the case where q is 2, and the general formula (2-3) represents the case where q is 3, similar to the above. In the case where q is 1, the structural unit of the general formula (3) is located at the end of the polysiloxane chain in the polysiloxane.

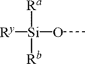

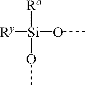

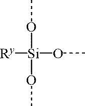

In the general formula, R^{y} has the same meaning as the R^{y} in the general formula (3), and R^{a} and R^{b} independently have the same meaning as the R^{y} and R⁴ in the general formula (3). The broken lines represent bonds to other Si atom.

Regarding O_{r/2} in the general formula (4), O_{r/2} in the case where r = 4 represents the following general formula (3-1). In the formula (3-1), the broken line represents a bond to an Si atom.

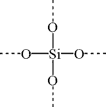

O_{4/2} represented by the above general formula (3-1) is generally referred to as a Q4 unit, and shows a structure in which all four bonds of an Si atom form siloxane bonds. Although Q4 has been described above, the general formula (4) may contain a hydrolyzable or polycondensable group in the bonds as in Q0, Q1, Q2, and Q3 units shown below. In addition, the general formula (4) may have at least one selected from the group consisting of Q1 to Q4 units.

Q0 Unit: A structure in which all four bonds of an Si atom are hydrolyzable or polycondensable groups (such as a halogen group, an alkoxy group, or a hydroxyl group, or a group capable of forming siloxane bonds).

Q1 unit: A structure in which one of the four bonds of an Si atom forms siloxane bonds and the remaining three are all hydrolyzable or polycondensable groups.

Q2 unit: A structure in which two of the four bonds of an Si atom form siloxane bonds and the remaining two are all hydrolyzable or polycondensable groups.

Q3 unit: A structure in which three of the four bonds of an Si atom form siloxane bonds and the remaining one is the hydrolyzable or polycondensable group.

Since the structural unit (4) represented by the general formula (4) has a structure close to SiO₂ in which the organic components are eliminated as much as possible, it is possible to impart chemical solution resistance, heat resistance, transparency, or organic solvent resistance to the obtained patterned cured film.

The structural unit (4) represented by the general-n (4) can be obtained by using tetraalkoxysilane, tetrahalosilane (for example, tetrachlorosilane, tetramethoxysilane, tetraethoxysilane, tetra-n-propoxysilane, and tetraisopropoxysilane) or oligomers thereof as a raw material, hydrolyzing them, and then polymerizing them (see “polymerization method” described later).

Examples of the oligomer include silicate compounds such as silicate 40 (average 5-mer, manufactured by TAMA CHEMICALS CO., LTD.), ethyl silicate 40 (average 5-mer, manufactured by COLCOAT CO., LTD.), silicate 45 (average 7-mer, manufactured by TAMA CHEMICALS CO., LTD.), M silicate 51 (average 4-mer, manufactured by TAMA CHEMICALS CO., LTD.), methyl silicate 51 (average 4-mer, manufactured by COLCOAT CO., LTD.), methyl silicate 53A (average 7-mer, manufactured by COLCOAT CO., LTD.), ethyl silicate 48 (average 10-mer, manufactured by COLCOAT CO., LTD.), and EMS-485 (mixed product of ethyl silicate and methyl silicate, manufactured by COLCOAT CO., LTD.). From the viewpoint of ease of handling, a silicate compound is preferably used.

In the case where the total amount of the polysiloxane according to the present embodiment is 100 mol% of Si atoms, the proportion of the structural unit (1) and/or the structural unit (2) in Si atoms is preferably 1 to 100 mol% in total. In addition, it may be more preferably 1 to 80 mol%, still more preferably 2 to 60 mol%, and particularly preferably 5 to 50 mol%.

In addition, in the case where the structural unit (3) and/or the structural unit (4) are included in addition to the structural unit (1) and/or the structural unit (2), the proportion of each structural unit in Si atoms is preferably 0 to 80 mol% of the structural unit (3) and 0 to 90 mol% of the structural unit (4) (the structural unit (3) and the structural unit (4) are 1 to 90 mol% in total). In addition, the structural unit (3) may be more preferably 2 to 70 mol%, still more preferably 5 to 40 mol%. In addition, the structural unit (4) may be more preferably 5 to 70 mol%, still more preferably 5 to 40 mol%. In addition, the sum of the structural unit (3) and the structural unit (4) may be more preferably 2 to 70 mol%, still more preferably 5 to 60 mol%.

Furthermore, Si atoms of the structural unit (1) and/or the structural unit (2) and the structural unit (3) and/or the structural unit (4) may be included in an amount of 1 to 100 mol%. It may be preferably 2 to 80 mol%, more preferably 5 to 60 mol%.

For example, the mole% of an Si atom can be determined from the peak area ratio in ²⁹Si NMR.

### [Other Structural Units (Optional Components)]

In the polysiloxane according to the present embodiment, in addition to the structural units described above, other structural units containing an Si atom (hereinafter, sometimes referred to as “optional components”) may be included in order to adjust the solubility in a solvent or the heat resistance and transparency of the patterned cured film. For example, such optional components include chlorosilane or alkoxysilane. In addition, chlorosilane and alkoxysilane are sometimes referred to as “other Si monomers”.

Specific examples of the chlorosilane include dimethyldichlorosilane, diethyldichlorosilane, dipropyldichlorosilane, diphenyldichlorosilane, bis(3,3,3-trifluoropropyl)dichlorosilane, methyl(3,3,3-trifluoropropyl)dichlorosilane, methyltrichlorosilane, ethyltrichlorosilane, propyltrichlorosilane, isopropyltrichlorosilane, phenyltrichlorosilane, methylphenyltrichlorosilane, trifluoromethyltrichlorosilane, pentafluoroethyltrichlorosilane, and 3,3,3-trifluoropropyltrichlorosilane.

Examples of alkoxysilane include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropylethoxysilane, diphenyldimethoxysilane, diphenyldiethoxysilane, diphenyldiphenoxysilane, bis(3,3,3-trifluoropropyl)dimethoxysilane, methyl(3,3,3-trifluoropropyl)dimethoxysilane, methyltrimethoxysilane, ethyltrimethoxysilane, propyltrimethoxysilane, isopropyltrimethoxysilane, phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, and 3,3,3-trifluoropropyltriethoxysilane.

The above-mentioned optional components may be used alone or in a mixture of two or more thereof.

Among them, phenyltrimethoxysilane, phenyltriethoxysilane, methylphenyldimethoxysilane, and methylphenyldiethoxysilane are preferred for the purpose of enhancing the heat resistance and transparency of the obtained patterned cured film, and dimethyldimethoxysilane and dimethyldiethoxysilane are preferred for the purpose of enhancing the flexibility of the obtained patterned cured film and preventing cracks and the like.

When the total Si atoms of the polysiloxane according to the present embodiment are 100 mol%, the proportion of Si atoms contained in the optional components is not particularly limited, but may be, for example, 0 to 99 mol%, preferably 0 to 95 mol%, and more preferably 10 to 85 mol%.

The molecular weight of the polysiloxane according to the present embodiment may be 500 to 50000 in terms of weight average molecular weight, preferably 800 to 40000, and more preferably 1000 to 30000. The molecular weight can be within a desired range by adjusting the amount of the catalyst and the temperature of the polymerization reaction.

### <Production Method for Polysiloxane>

Next, a polymerization method for obtaining the polysiloxane according to the present embodiment will be described. Regarding the structural unit (1) and the structural unit (2), a desired polysiloxane can be obtained by a hydrolytic polycondensation reaction using an alkoxysilane represented by the general formula (X) and the general formula (Y) or halosilane represented by a general formula (9) and a general formula (10). The same applies to the case where alkoxysilane and halosilane are mixed and used. Therefore, the polysiloxane according to the present embodiment is also a hydrolyzed polycondensate.

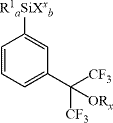

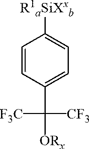

In the general formula (9) and the general formula (10), R¹, a, and b are the same as those in the general formula (X), and X^{x} is a halogen atom.

Regarding the structural unit (3), a desired polysiloxane can be obtained by a hydrolytic polycondensation reaction using the alkoxysilane or the like exemplified above.

Regarding the structural unit (4), a desired polysiloxane can be obtained by a hydrolytic polycondensation reaction using the alkoxysilane, halosilane, or the like exemplified above.

The hydrolytic polycondensation reaction can be carried out by a general method in the hydrolysis and the condensation reaction of halosilanes (preferably chlorosilane) and alkoxysilane.

As a specific example, first, a predetermined amount of halosilanes and alkoxysilane are collected in a reaction vessel at room temperature (in particular, an atmosphere temperature not heated or cooled, and usually about 15° C. or more and about 30° C. or less; the same shall apply hereinafter), and then water for hydrolyzing the halosilanes and alkoxysilane, a catalyst for causing the polycondensation reaction to proceed, and, if desired, a reaction solvent are added to the reaction vessel to prepare a reaction solution. In this case, the order of charging reaction materials is not limited to this, and the reaction solution can be prepared by charging the reaction materials in any order. In addition, in the case where another Si monomer is used in combination, it may be added to the reaction vessel in the same manner as the halosilanes and alkoxysilane.

Next, the reaction solution is stirred, and the hydrolysis and the condensation reaction are allowed to proceed at a predetermined temperature for a predetermined time, whereby the polysiloxane according to the present embodiment can be obtained. The time required for the hydrolytic condensation depends on the type of the catalyst, and is usually 3 hours or more and 24 hours or less, and the reaction temperature is room temperature (e.g., 25° C.) or more and 200° C. or less. In the case where heating is performed, in order to prevent the unreacted raw material, water, the reaction solvent, and/or the catalyst in the reaction system from being distilled off to the outside of the reaction system, it is preferred to make the reaction vessel a closed system or attach a reflux device such as a condenser to reflux the reaction system. After the reaction, from the viewpoint of handling the polysiloxane according to the present embodiment, it is preferred to remove the water remaining in the reaction system, the alcohol to be produced, and the catalyst. The removal of water, alcohol, and the catalyst may be carried out in an extraction operation, or a solvent such as toluene that does not adversely affect the reaction may be added to the reaction system and azeotropically removed in a Dean-Stark tube.

The amount of water used in the hydrolysis and the condensation reaction is not particularly limited. From the viewpoint of reaction efficiency, the amount of water used in the hydrolysis and the condensation reaction is preferably 0.5 times or more and 5 times or less with respect to the total number of moles of the hydrolyzable group (alkoxy group and halogen atom group) contained in the alkoxysilane and halosilanes as the raw material.

Although the catalyst for advancing the polycondensation reaction is not particularly limited, an acid catalyst and a base catalyst are preferably used. Specific examples of the acid catalyst include a polyvalent carboxylic acid such as hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosic acid, formic acid, maleic acid, malonic acid, or succinic acid, or an anhydride thereof, and the like. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, sodium carbonate, and tetramethylammonium hydroxide, and the like. The amount of the catalyst used is preferably 1.0 × 10⁻⁵ times or more and 1.0 × 10⁻¹ times or less with respect to the total number of moles of the hydrolyzable group (alkoxy group and halogen-atom group) contained in the alkoxysilane and halosilanes as the raw material.

In the hydrolysis and the condensation reaction, the reaction solvent is not necessarily used, and a raw material compound, water, and a catalyst can be mixed and hydrolytically condensed. On the other hand, in the case where a reaction solvent is used, the type thereof is not particularly limited. Among them, from the viewpoint of solubility in the raw material compound, water, and the catalyst, a polar solvent is preferable, and an alcohol-based solvent is more preferable. Specific examples thereof include methanol, ethanol, 1-propanol, 2-propanol, 1-butanol, 2-butanol, diacetone alcohol, and propylene glycol monomethyl ether, and the like. In the case where the reaction solvent is used, any amount necessary for the hydrolytic condensation reaction to proceed in a homogeneous system can be used. In addition, a solvent described later may be used as the reaction solvent.

### 3: Resin Composition

In an embodiment, a resin composition containing a polysiloxane and a solvent can be provided. Examples of the solvent contained in the resin composition include at least one compound selected from a group consisting of propylene glycol monomethyl ether acetate, propylene glycol monomethyl ether, cyclohexanone, ethyl lactate, ʏ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols, and glycol ethers and glycol ether esters.

Specific examples of the glycol, glycol ether, and glycol ether ester include CELTOL (registered trademark) manufactured by Daicel Corporation, and Hisorb (registered trademark) manufactured by TOHO CHEMICAL INDUSTRY Co., Ltd. Specific examples thereof include, but are not limited to, cyclohexanol acetate, dipropylene glycol dimethyl ether, propylene glycol diacetate, dipropylene glycol methyl-n-propyl ether, dipropylene glycol methyl ether acetate, 1,4-butanediol diacetate, 1,3-butilene glycol diacetate, 1,6-hexanediol diacetate, 3-methoxybutylacetate, ethylene glycol monobutyl ether acetate, diethylene glycol monoethyl ether acetate, diethylene glycol monobutyl ether acetate, triacetin, 1,3-butylene glycol, propylene glycol-n-propyl ether, propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, tripropylene glycol dimethyl ether, and triethylene glycol dimethyl ether.

In an embodiment, the amount of the solvent contained in the resin composition is preferably 40% by mass or more and 95% by mass or less, more preferably 50% by mass or more and 90% by mass or less. Making the content of the solvent within the above range makes it possible to coat and form a uniform resin film with an appropriate thickness. In addition, two or more of the above solvents may be used in combination as the solvent.

### [Additive Agent (Optional Component)]

In an embodiment, the following components can be contained in the resin composition as the additive agent as long as the excellent properties of the coating solution are not significantly impaired.

For example, an additive agent such as a surfactant may be included in order to improve coatability, a leveling property, film formability, storage stability or a defoaming property, and the like. Specific examples thereof include commercially available surfactants, product name MEGAFACE manufactured by DIC Corporation, product number F142D, F172, F173, or F183, product name Fluorad manufactured by 3M Japan Limited, product number FC-135, FC-170C, FC-430, or FC-431, product name Surflon manufactured by AGC Seimi Chemical Co., Ltd., product number S-112, S-113, S-131, S-141, or S-145, and product name SH-28PA, SH-190, SH-193, SZ-6032, or SF-8428 manufactured by Toray Dow Corning Silicone Co., Ltd.

In the case of adding these surfactants, the blending amount of the surfactant is preferably 0.001 parts by mass or more and 10 parts by mass or less when the amount of the polysiloxane is 100 parts by mass. MEGAFACE is a product name of a fluorine-based additive agent (surfactant/surface modifier) manufactured by DIC Corporation, Fluorad is a product name of a fluorosurfactant manufactured by 3M Japan Limited, and Surflon is a product name of a fluorosurfactant manufactured by AGC Seimi Chemical Co., Ltd., each of which is registered as a trademark.

A curing agent can be blended as another component in order to improve the chemical solution resistance of the obtained cured film or patterned cured film. Examples of the curing agent include a melamine curing agent, a urea resin curing agent, a polybasic acid curing agent, an isocyanate curing agent, or an epoxy curing agent. It is thought that the curing agent mainly reacts with the “—OH″ of the structural unit (3) and/or the structural unit (4) to form a crosslinked structure.

Specific examples thereof include isocyanates such as isophorone diisocyanate, hexamethylene diisocyanate, tolylene diisocyanate, or diphenylmethane diisocyanate, and isocyanurates thereof, blocked isocyanates thereof or biuretes thereof, amino compounds such as melamine resins such as alkylated melamine, methylol melamine and imino melamine, and urea resins, or epoxy curing agents having two or more epoxy groups obtained by reacting polyvalent phenol such as bisphenol A with epichlorohydrin. Specifically, a curing agent having a structure represented by a formula (11) is more preferable, and specifically, a melamine derivative represented by formulas (11a) to (11d) or a urea derivative (manufactured by SANWA CHEMICAL CO., LTD.) is exemplified (in the formula (11), the broken line represents a bond).

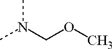

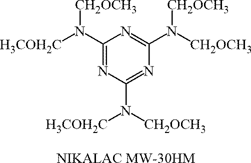

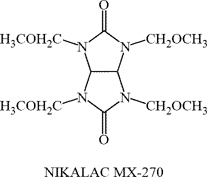

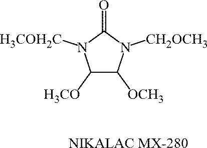

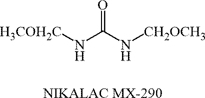

In the case of adding these curing agents, the amount of the curing agent is preferably 0.001 parts by mass or more and 10 parts by mass or less when theamount of the polysiloxane is 100 parts by mass.

### 4: Cured Film

In an embodiment, a cured film formed by curing a polysiloxane is provided. In addition, in an embodiment, a cured film formed by curing a resin composition is provided. The cured film according to these embodiments can be used as a coating material for a liquid crystal display or an organic EL display, a coating material for an image sensor, a sealing material in the field of semiconductors, and a hard mask material for a multilayer resist.

### 5: Production Method for Cured Film

In an embodiment, a cured film formed by curing a polysiloxane or resin composition is provided. A cured film can be formed by coating the polysiloxane according to the present embodiment onto the substrate and then heating it at a temperature of 100° C. to 350° C. Alternatively, a cured film can be formed by coating the resin composition according to the present embodiment onto the substrate and then heating it at a temperature of 100° C. to 350° C.

### 6: Photosensitive Resin Composition

In an embodiment, there is provided a photosensitive resin composition containing the polysiloxane according to the embodiment described above as a component (A), at least one photosensitizing agent selected from a group consisting of a quinone diazide compound, a photoacid generator, a photobase generator, and a photo-radical generator as a component (B), and a solvent as a component (C).

Since the polysiloxane as the component (A) has been described above, a detailed description thereof will be omitted. In this case, the components (B) and (C) will be described.

### (B) Photosensitizing Agent

For example, although at least one photosensitizing agent selected from a group consisting of naphthoquinone diazide, a photoacid generator, a photobase generator, and a photo-radical generator can be used, the present invention is not limited to these.

Naphthoquinone diazide will be described. A naphthoquinone diazide compound releases nitrogen molecules upon exposure to be decomposed and generates a carboxylic acid group in the molecule, thereby improving the solubility of the photosensitive resin film in an alkaline developer. In addition, at an unexposed site, the naphthoquinone diazide compound suppresses the alkaline solubility of the photosensitive resin film. Therefore, using a photosensitive resin composition containing a naphthoquinone diazide compound causes a contrast of solubility in an alkali developer at the unexposed site and the exposed site, and a positive pattern can be formed.

For example, the naphthoquinone diazide compound is a compound which has a quinone diazide group such as the 1,2-quinone diazide group. Examples of the 1,2-quinone diazide compound include 1,2-naphthoquinone-2-diazide-4-sulfonic acid, 1,2-naphthoquinone-2-diazide-5-sulfonic acid, 1,2-naphthoquinone-2-diazide-4-sulfonyl chloride, and 1,2-naphthoquinone-2-diazide-5-sulfonyl chloride. Using the quinone diazide compound makes it possible to obtain a positive photosensitive resin composition that is sensitive to i-rays (wavelength 365 nm), h-rays (wavelength 405 nm), and g-rays (436 nm) of a mercury lamp, which is a general ultraviolet ray.

Examples of commercially available naphthoquinone diazide compounds include NT series, 4NT series, and PC-5 manufactured by Toyo Gosei Co., Ltd., and TKF series and PQ-C manufactured by SANBO CHEMICAL INDUSTRYCO., LTD.

Although the blending amount of the naphthoquinone diazide as a photosensitizing agent in the present photosensitive resin composition is not necessarily limited, the blending amount of the naphthoquinone diazide as a photosensitizing agent when the amount of the polysiloxane according to thepresent embodiment is 100 parts by mass is preferably, for example, 2 parts by mass or more and 40 parts by mass or less, and more preferably 5 parts by mass or more and 30 parts by mass or less. Using an appropriate amount of naphthoquinone diazide makes it easy to achieve both sufficient patterning performance and storage stability of the composition.

The photoacid generator will be described. The photoacid generator is a compound that generates an acid upon irradiation with light. The acid generated at the exposed site promotes the silanol condensation reaction, i.e., the sol-gel polymerization reaction, so that the dissolution rate by the alkaline developer can be remarkably reduced, i.e., resistance to the alkaline developer can be realized. In addition, the case where the polysiloxane according to the present embodiment contains an epoxy group or an oxetane group is preferable because each curing reaction can be accelerated. On the other hand, this effect does not occur in the unexposed site, the unexposed site is dissolved by the alkaline developer, and a negative pattern corresponding to the shape of the exposed site is formed.

Specific examples of the photoacid generator include sulfonium salts, iodonium salts, sulfonyldiazomethanes, N-sulfonyloxyimides, or oxime-O-sulfonates. These photoacid generators may be used alone or in combination of two or more thereof. Specific examples of the commercially available product include, but are not limited to, product name: Irgacure 290, Irgacure PAG121, Irgacure PAG103, Irgacure CGI1380, Irgacure CGI725 (manufactured by BASF, USA), product name: PAI-101, PAI-106, NAI-105, NAI-106, TAZ-110, TAZ-204 (manufactured by Midori Kagaku Co., Ltd.), product name: CPI-200K, CPI-210S, CPI-101A, CPI-110A, CPI-100P, CPI-110P, CPI-310B, CPI-100TF, CPI-110TF, HS-1, HS-1A, HS-1P, HS-1N, HS-1TF, HS-1NF, HS-1MS, HS-1CS, LW-S1, LW-S1NF (manufactured by San-Apro Ltd.), product name: TFE-triazine, TME-triazine, or MP-triazine (manufactured by SANWA CHEMICAL CO., LTD.).

Although the blending amount of the photoacid generator as a photosensitizer in the present photosensitive resin composition is not necessarily limited, the blending amount of the photoacid generator as a photosensitizer when the amount of the polysiloxane according to the present embodiment is 100 parts by mass is preferably, for example, 0.01 parts by mass or more and 10 parts by mass or less, and more preferably 0.05 parts by mass or more and 5 parts by mass or less. Using an appropriate amount of the photoacid generator makes it easy to achieve both sufficient patterning performance and storage stability of the composition.

Next, the photobase generator will be described. The photobase generator is a compound that generates a base (anion) upon irradiation with light. The base generated at the exposed site promotes the sol-gel reaction, so that the dissolution rate of the alkaline developer can be remarkably reduced, i.e., resistance to the alkaline developer can be realized. On the other hand, this effect does not occur at the unexposed site, the unexposed site is dissolved by the alkaline developer, and a negative pattern corresponding to the shape of the exposed site is formed.

Specific examples of the photobase generator include amides, amine salts, and the like. Specific examples of the commercially available product include, but are not limited to, product name: WPBG-165, WPBG-018, WPBG-140, WPBG-027, WPBG-266, WPBG-300, WPBG-345 (manufactured by FUJIFILM Wako Pure Chemical Corporation), 2-(9-Oxoxanthen-2-yl)propionic Acid 1,5,7-Triazabicyclo[4.4.0]dec-5-ene Salt, 2-(9-Oxoxanthen-2-yl)propionic Acid, Acetophenone O-Benzoyloxime, 2-Nitrobenzyl Cyclohexylcarbamate, 1,2-Bis(4-methoxyphenyl)-2-oxoethyl Cyclohexylcarbamate (manufactured by Tokyo Chemical Industry, Co., Ltd.), and product name: EIPBG, EITMG, EINAP, NMBC (manufactured by EIWEISS Chemical Corporation).

These photoacid generators and photobase generators may be used alone or in combination of two or more thereof or in combination with other compounds.

Specific examples of the combination with other compounds include combinations with amines such as 4,4′-bis(dimethylamino)benzophenone, 4,4′-bis(diethylamino)benzophenone, diethanolmethylamine, dimethylethanolamine, triethanolamine, ethyl-4-dimethylaminobenzoate, and 2-ethylhexyl-4-dimethylaminobenzoate, and further combinations with iodonium salts such as diphenyliodonium chloride, and combinations of dyes such as methylene blue with amines.

Although the blending amount of the photobase generator as the photosensitizer in the present photosensitive resin composition is not necessarily limited, the blending amount of the photobase generator as the photosensitizer when the amount of the polysiloxane according to the present embodiment is 100 parts by mass is preferably, for example, 0.01 parts by mass or more and 10 parts by mass or less, and more preferably 0.05 parts by mass or more and 5 parts by mass or less. Using the photobase generator in the amounts indicated here makes it possible to further improve the chemical solution resistance of the obtained patterned cured film and the storage stability of the composition.

In addition, the present photosensitive resin composition may further contain a sensitizer. The reaction of the photosensitizing agent is accelerated in the exposure process, and the sensitivity and the pattern resolution are improved by containing the sensitizer.

The sensitizer is not particularly limited, but preferably a sensitizer which is vaporized by heat treatment or a sensitizer which is bleached by light irradiation is used. The sensitizer needs to have light absorption with respect to an exposure wavelength (for example, 365 nm (i-rays), 405 nm (h-rays), or 436 nm (g-rays)) in the exposure process, but if the sensitizer remains in the patterned cured film as it is, absorption is present in a visible light area, and thus the transparency is lowered. Therefore, in order to prevent a decrease in transparency due to the sensitizer, the sensitizer used is preferably a compound which is vaporized by a heat treatment such as thermal curing, or a compound which is bleached by light irradiation such as bleaching exposure described later.

Specific examples of the sensitizer vaporized by the above heat treatment and the sensitizer bleached by light irradiation include coumarin such as 3,3′-carbonylbis(diethylaminocoumarin), anthraquinone such as 9,10-anthraquinone, aromatic ketones such as benzophenone, 4,4′-dimethoxybenzophenone, acetophenone, 4-methoxyacetophenone, and benzaldehyde, and condensed aromatics such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, and 9,10-bis(trimethylsilylethynyl)anthracene. Commercially available sensitizers include ANTHRACURE (manufactured by Kawasaki Kasei Chemicals Ltd.) and the like.

In the case of adding these sensitizers, the blending amount thereof is preferably 0.001 parts by mass or more and 10 parts by mass or less with respect to 100 parts by mass of the polysiloxane according to the present embodiment.

In addition, whether each of the above-described sensitizers is used alone or in a mixture of two or more thereof may be appropriately determined by a person skilled in the art depending on the application, environment of use, and restriction.

### 7: Patterned Cured Film

In an embodiment, a patterned cured film having a pattern structure obtained by curing a photosensitive resin composition is provided. In addition, the pattern structure may include a concave-convex structure having a pattern size of 500 µm or less. In addition, the “patterned cured film” in the present specification is a cured film obtained by developing a pattern after a step of development and curing the obtained pattern.

### 8: Production Method for Patterned Cured Film

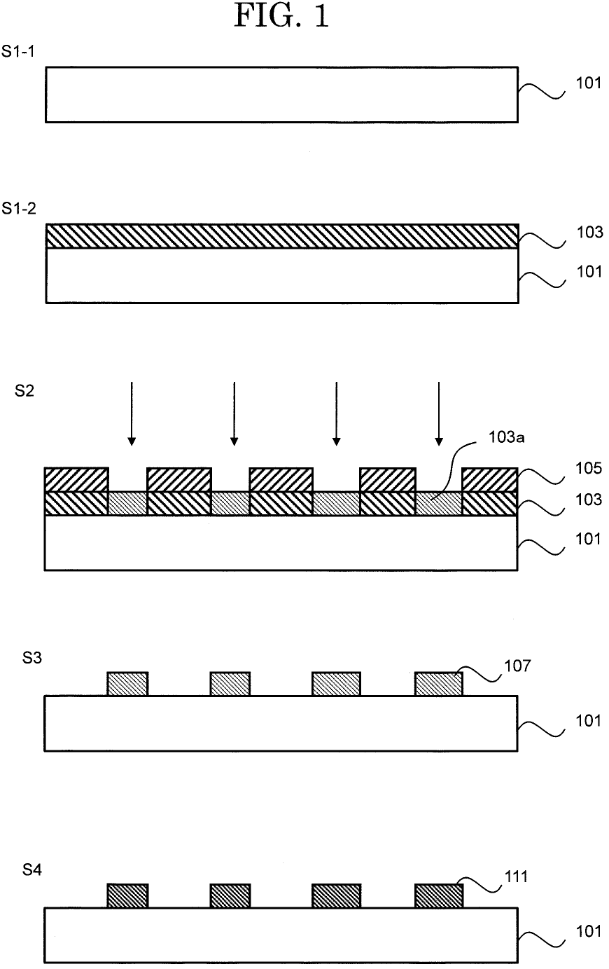

FIG. 1 is a schematic diagram illustrating a production method for a negative patterned cured film 111 according to an embodiment of the present invention. The production method for the patterned cured film 111 according to the present embodiment may include the following steps 1 to 4. Although FIG. 1 shows the negative patterned cured film 111, the present invention can also be used for a positive patterned cured film.

First step: a step of film formation applying a photosensitive resin composition on a substrate 101 to form a photosensitive resin film 103.

Second step: a step of exposing the photosensitive resin film 103.

Third step: a step of developing the photosensitive resin film after exposing to form a patterned resin film 107.

Fourth step: a step of curing by heating the patterned resin film to convert the patterned resin film to the patterned cured film 111.

### [First Step]

The substrate 101 is prepared (step S1-1). The substrate 101 to which the photosensitive resin composition according to the present embodiment is applied is selected from a substrate of a silicon wafer, a metal, a glass, a ceramic, and a plastic depending on the application of the patterned cured film to be formed. Specifically, examples of the substrate used in a semiconductor, a display, or the like include silicon, silicon nitride, glass, polyimide (Kapton), polyethylene terephthalate, polycarbonate, and polyethylene naphthalate. In addition, the substrate 101 may have any layer such as silicon, metal, glass, ceramic, or resin on the surface thereof, and “on the substrate” may be the surface of the substrate or through the layer.

A known method such as spin coating, dip coating, spray coating, bar coating, applicator, ink jet, or roll coater can be used as a method of applying the photosensitive resin composition according to the present embodiment on the substrate 101 without any particular limitation.

After that, the photosensitive resin film 103 can be obtained by drying the substrate 101 coated with the photosensitive resin composition (step S1-2). The drying treatment may be performed as long as the solvent can be removed to such an extent that the obtained photosensitive resin film 103 does not easily flow or deform, and may be heated, for example, at 80° C. to 120° C. for 30 seconds or more and 5 minutes or less.

### [Second Step]

Next, the photosensitive resin film 103 obtained in the first step is shielded by a light-shielding plate (photo mask) 105 with a desired shape for forming a target pattern, and an exposure process for irradiating the photosensitive resin film 103 with light is performed to obtain the photosensitive resin film 103 after exposing (step S2). The photosensitive resin film 103 after exposing includes the exposed site 103a and an unexposed site.

A known method can be used for the exposure process. A light beam having a 10 nm to 600 nm wavelength can be used as a light source. Specifically, a low-pressure mercury lamp, a high-pressure mercury lamp, an ultra-high-pressure mercury lamp, a KrF excimer laser (wavelength 248 nm), an ArF excimer laser (wavelength 193 nm), an EUV beam (wavelength 13.5 nm), or the like can be used. The exposure amount can be adjusted according to the type and amount of the photosensitizing agent to be used, the production process, and the like, and is not particularly limited, but is about 1 to 10000 mJ/cm², preferably about 10 to 5000 mJ/cm².

After the exposure, if necessary, post-exposure heating may be performed before the step of development. The temperature of the post-exposure heating is preferably 60 to 180° C., and the time of the post-exposure heating is preferably 30 seconds to 10 minutes.

### [Third Step]

Next, a film (hereinafter, sometimes referred to as the “patterned resin film”) 107 with a desired pattern can be formed by developing the photosensitive resin film 103 after exposing obtained in the second step to remove the portions other than the exposed sites 103a (step S3). In addition, in FIG. 1, the negative patterned cured film 111 is obtained, but in the positive patterned cured film, the exposed sites 103a are removed by developing, and the photosensitive resin film 103 shielded by the light-shielding plate 105 becomes the patterned resin film.

Development is to form a pattern by dissolving and cleaning and removing the unexposed sites or exposed sites using an alkaline solution as a developer. As described above, the unexposed sites are dissolved and cleaned and removed to obtain a negative patterned resin film and the exposed sites are dissolved and cleaned and removed to obtain a positive patterned resin film, respectively.

The developer to be used is not particularly limited as long as it can remove a desired photosensitive resin film by a predetermined developing method. Specific examples include an alkali aqueous solution using inorganic alkali, primary amines, secondary amines, tertiary amines, alcohol amines, quaternary ammonium salts, and mixtures thereof.

More specific examples include an alkaline aqueous solution such as potassium hydroxide, sodium hydroxide, ammonia, ethylamine, diethylamine, triethylamine, triethanolamine, and tetramethylammonium hydroxide (abbreviation: TMAH). Among them, the TMAH aqueous solution is preferably used, and in particular, the TMAH aqueous solution of 0.1% by mass or more and 5% by mass or less, more preferably 2% by mass or more and 3% by mass or less is preferably used.

A known method such as a dipping method, a paddle method, or a spraying method can be used as the developing method. The development time may be 0.1 minutes or more and 3 minutes or less, and preferably 0.5 minutes or more and 2 minutes or less. Thereafter, cleaning, rinsing, drying, or the like may be performed as needed to form the target patterned resin film 107 on the substrate 101.

In addition, after the patterned resin film 107 is formed, the patterned resin film 107 is preferably subjected to bleaching exposure. The purpose is to improve the transparency of the finally obtained patterned cured film 111 by photodecomposing the photosensitizing agent remaining in the patterned resin film 107. The bleaching exposure can be performed in the same manner as in the second step.

### [Fourth Step]

Next, the patterned resin film (including the patterned resin film bleached by exposure) 107 obtained in the third step is heat-treated to obtain the final patterned cured film 111 (step S4). The heat treatment makes it possible to condense the alkoxy groups and silanol groups remaining as unreacted groups in the polysiloxane. In addition, if the photosensitizing agent remains, it can be removed by thermal decomposition.

The heating temperature at this time is preferably 80° C. or more and 400° C. or less, and more preferably 100° C. or more and 350° C. or less. The heat treatment time may be 1 minute or more and 90 minutes or less, preferably 5 minutes or more and 60 minutes or less. The condensation, curing reaction, and thermal decomposition of the photosensitizing agent are sufficiently advanced by setting the temperature to be within the above range, and the desired chemical solution resistance, heat resistance, and transparency can be obtained. In addition, it is possible to suppress thermal decomposition of the polysiloxane and fissures (cracks) of the formed film, and it is possible to obtain a film having good adhesion to the substrate. The target patterned cured film 111 can be formed on the substrate 101 by this heat treatment.

### [Optical Member]

The cured film or the patterned cured film described above can be used as an anti-reflective film, a lens, an optical waveguide, a light-shielding film, or a flattening film. In addition, the anti-reflective film, the lens, the optical waveguide, the light-shielding film, or the flattening film can be used for a solid-state imaging device or a display device.

Examples of an electronic device having the solid-state imaging device include a video camera, a digital camera, a camera-equipped mobile phone, a copying machine, a gaming machine, and an automatic door.

Examples of an imaging device having the solid-state imaging device include an endoscope camera, a microscope, a medical camera utilizing infrared light reception, an in-vehicle camera, a surveillance camera, a person authentication camera, and an industrial camera.

Examples of the display device include a liquid crystal display, an organic EL display, a quantum-dot display, and a micro LED display.

### EXAMPLES

Hereinafter, although the present invention will be described in more detail with reference to Examples, the present invention is not limited to the following Examples unless the gist thereof is exceeded.

In the following examples, unless otherwise indicated, some compounds are designated as follows.

### PGMEA: Propylene Glycol Monomethyl Ether Acetate

HFA—Si (m-isomer): A compound represented by the following chemical formula

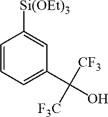

HFA—Si (p-isomer): A compound represented by the following chemical formula

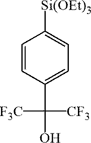

Devices and measurement conditions used for various measurements will be described.

### Gel-Permeation Chromatography GPC

The weight-average molecular weight in terms of polystyrene was measured using a high-speed GPC device manufactured by Tosoh Corporation, with the device name HLC-8320GPC.

### Example 1 (m-isomer/p-isomer = 95/5)

First, HFA—Si (m-isomer) (0.95 g, 2.3 mmol) and HFA—Si (p-isomer) (0.05 g, 0.12 mmol) were mixed to obtain a silicon-containing monomer mixture having a ratio of m-isomer/p-isomer shown in Table 1.

Next, pure water (0.14 g, 7.6 mmol) and acetic acid (0.004 g, 0.07 mmol) were added to the mixture, and the mixture was stirred at 40° C. for 1 hour, 70° C. for 1 hour, and 100° C. for 3 hours. Next, cyclohexanone (5 g) and pure water (1 g) were added to perform water washing and separation. Cyclohexanone in the obtained organic layer was distilled off by an evaporator to obtain 3 g of a polysiloxane solution 1 having a solid concentration of 33 wt%.

As a result of measuring the molecular weight by GPC, the weight-average molecular weight (Mw) was 1850. In RI of GPC, no peak of the raw material (sum of HFA—Si (m-isomer) and HFA—Si (p-isomer)) was confirmed, and the conversion rate was 100%.

### Example 2 (m-isomer/p-isomer = 90/10)

First, HFA—Si (m-isomer) (0.90 g, 2.2 mmol) and HFA—Si (p-isomer) (0.10 g, 0.24 mmol) were mixed to obtain a silicon-containing monomer mixture having a ratio of m-isomer/p-isomer shown in Table 1.

Next, pure water (0.14 g, 7.6 mmol) and acetic acid (0.004 g, 0.07 mmol) were added to the mixture, and the mixture was stirred at 40° C. for 1 hour, 70° C. for 1 hour, and 100° C. for 3 hours. Next, cyclohexanone (5 g) and pure water (1 g) were added to perform water washing and separation. Cyclohexanone in the obtained organic layer was distilled off by an evaporator to obtain 3 g of a polysiloxane solution 2 having a solid concentration of 33 wt%.

As a result of measuring the molecular weight by GPC, the weight-average molecular weight (Mw) was 1850. In RI of GPC, no peak of the raw material (sum of HFA—Si (m-isomer) and HFA—Si (p-isomer)) was confirmed, and the conversion rate was 100%.

### Example 3 (m-isomer/p-isomer = 75/25)

First, HFA—Si (m-isomer) (0.75 g, 1.8 mmol) and HFA—Si (p-isomer) (0.25 g, 0.62 mmol) were mixed to obtain a silicon-containing monomer mixture having a ratio of m-isomer/p-isomer shown in Table 1.

Next, pure water (0.14 g, 7.6 mmol) and acetic acid (0.004 g, 0.07 mmol) were added to the mixture, and the mixture was stirred at 40° C. for 1 hour, 70° C. for 1 hour, and 100° C. for 3 hours. Next, cyclohexanone (5 g) and pure water (1 g) were added to perform water washing and separation. Cyclohexanone in the obtained organic layer was distilled off by an evaporator to obtain 3 g of a polysiloxane solution 3 having a solid concentration of 33 wt%. As a result of measuring the molecular weight by GPC, the weight-average molecular weight (Mw) was 1920. In RI of GPC, no peak of the raw material (sum of HFA—Si (m-isomer) and HFA—Si (p-isomer)) was confirmed, and the conversion rate was 100%.

### Example 4 (m-isomer/p-isomer = 50/50)

First, HFA—Si (m-isomer) (0.5 g, 1.2 mmol) and HFA—Si (p-isomer) (0.5 g, 1.2 mmol) were mixed to obtain a silicon-containing monomer-mixture having a ratio of m-isomer/p-isomer shown in Table 1.

Next, pure water (0.14 g, 7.6 mmol) and acetic acid (0.004 g, 0.07 mmol) were added to the mixture, and the mixture was stirred at 40° C. for 1 hour, 70° C. for 1 hour, and 100° C. for 3 hours. Next, cyclohexanone (5 g) and pure water (1 g) were added to perform water washing and separation. Cyclohexanone in the obtained organic layer was distilled off by an evaporator to obtain 3 g of a polysiloxane solution 4 having a solid concentration of 33 wt%. As a result of measuring the molecular weight by GPC, the weight-average molecular weight (Mw) was 1950. In RI of GPC, no peak of the raw material (sum of HFA—Si (m-isomer) and HFA—Si (p-isomer)) was confirmed, and the conversion rate was 100%.

### Example 5 (m-isomer/p-isomer = 25/75)

First, HFA—Si (m-isomer) (1.0 g, 2.4 mmol) and HFA—Si (p-isomer) (3.0 g, 7.4 mmol) were mixed to obtain a silicon-containing monomer mixture having a ratio of m-isomer/p-isomer shown in Table 1.

Next, pure water (0.56 g, 31.0 mmol) and acetic acid (0.02 g, 0.37 mmol) were added to the mixture, and the mixture was stirred at 40° C. for 1 hour, 70° C. for 1 hour, and 100° C. for 3 hours. Next, cyclohexanone (10 g) and pure water (5 g) were added to perform water washing and separation. Cyclohexanone in the obtained organic layer was distilled off by an evaporator to obtain 10 g of a polysiloxane solution 5 having a solid concentration of 33 wt%. As a result of measuring the molecular weight by GPC, the weight-average molecular weight (Mw) was 2210. In RI of GPC, no peak of the raw material (sum of HFA—Si (m-isomer) and HFA—Si (p-isomer)) was confirmed, and the conversion rate was 100%.

### Example 6 (m-isomer/p-isomer = 5/95)

First, HFA—Si (m-isomer) (0.25 g, 0.62 mmol) and HFA—Si (p-isomer) (4.75 g, 7.4 mmol) were mixed to obtain a silicon-containing monomer mixture having a ratio of m-isomer/p-isomer shown in Table 1.

Next, pure water (0.70 g, 38.8 mmol) and acetic acid (0.02 g, 0.37 mmol) were added to the mixture, and the mixture was stirred at 40° C. for 1 hour, 70° C. for 1 hour, and 100° C. for 3 hours. Next, cyclohexanone (10 g) and pure water (5 g) were added to perform water washing and separation. Cyclohexanone in the obtained organic layer was distilled off on an evaporator to obtain 12 g of a polysiloxane solution 6 having a solid concentration of 33 wt%. As a result of measuring the molecular weight by GPC, the weight-average molecular weight (Mw) was 2500. In RI of GPC, no peak of the raw material (sum of HFA—Si (m-isomer) and HFA—Si (p-isomer)) was confirmed, and the conversion rate was 100%.

### Comparative Example 1 (m-isomer/p-isomer = 100/0)

First, HFA—Si (m-isomer) (1.0 g, 2.5 mmol) was prepared. Next, pure water (0.14 g, 7.6 mmol) and acetic acid (0.004 g, 0.07 mmol) were added to the silicon-containing monomer, and the mixture was stirred at 40° C. for 1 hour, 70° C. for 1 hour, and 100° C. for 3 hours. Next, cyclohexanone (5 g) and pure water (1 g) were added to perform water washing and separation. Cyclohexanone in the obtained organic layer was distilled off by an evaporator to obtain 3 g of a polysiloxane solution 7 having a solid concentration of 33 wt%. As a result of measuring the molecular weight by GPC, the weight-average molecular weight (Mw) was 1500. In RI of GPC, the conversion rate calculated from the area % of the peak of the raw material (sum of HFA—Si (m-isomer) and HFA—Si (p-isomer)) and the area % of the polymer peak was 25%.

For each of the polysiloxane of the Examples and the Comparative Example, the measurement results of the conversion rate from the raw material to the polysiloxane and the weight-average molecular weight after 3 hours from the start of the reaction are shown in Table 1.

TABLE 1

| | Ratio of m-isomer/p-isomer | Conversion rate (%) | Weight-average molecular weight (Mw) |
|---|---|---|---|
| Example 1 | 95/5 | 100 | 1800 |
| Example 2 | 90/10 | 100 | 1820 |
| Example 3 | 75/25 | 100 | 1890 |
| Example 4 | 50/50 | 100 | 1830 |
| Example 5 | 25/75 | 100 | 2180 |
| Example 6 | 5/95 | 100 | 2470 |
| Comparative Example 1 | 100/0 | 20 | 1400 |

As shown in Table 1, it was found that the addition of HFA—Si (p-isomer) increased the conversion rate and the weight-average molecular weight as compared with Comparative Example 1.

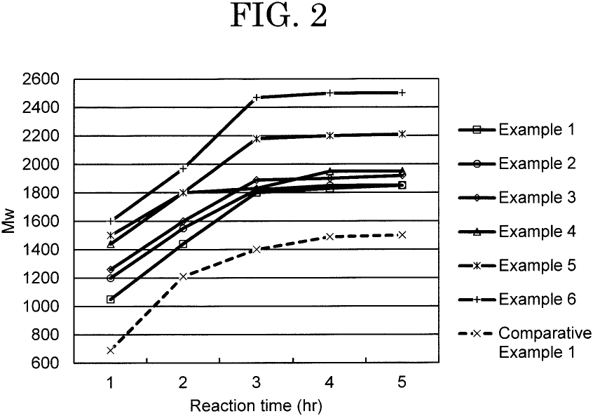

In addition, FIG. 2 shows the relationship between the reaction time and the weight-average molecular weight of the polysiloxane of the Examples and the Comparative Example. It is clear from the figure that the weight-average molecular weight of the polysiloxane of Comparative Example 1 is small. Although the detailed reasons are not clear from Table 1 and FIG. 2, it is assumed that the steric hindrance of HFA—Si (p-isomer) is small, so that the hydrolysis is fast, and the silanols having the HFIP group present in the system act catalytically to accelerate the conversion rate and increase the weight-average molecular weight.

### Example 7

1 g of the polysiloxane solution of Example 5 was put into a vial and stored in a refrigerator. The weight-average molecular weight (Mw) was measured by GPC one day and four days after the beginning of storage. The results were Mw2230 after one day and Mw2250 after four days.

### Example 8

1 g of the polysiloxane solution of Example 6 was put into a vial and stored in a refrigerator. The weight-average molecular weight (Mw) was measured by GPC one day after and four days after the beginning of storage. The results were Mw2450 after one day and Mw2500 after four days.

### Comparative Example 2 (m-isomer/p-isomer = 0/100)

HFA—Si (p-isomer) (5.0 g, 12.3 mmol), pure water (0.7 g, 38.8 mmol), and acetic acid (0.02 g, 0.37 mmol) were added, and the mixture was stirred at 40° C. for one hour, 70° C. for one hour, and 100° C. for three hours. Next, cyclohexanone (12 g) and pure water (5 g) were added to perform water washing and separation. The obtained organic layer cyclohexanone was distilled off by an evaporator to obtain 10 g of a polysiloxane solution 8 having a solid concentration of 33 wt%. As a result of measuring the molecular weight by GPC, the weight-average molecular weight (Mw) was 2480.

1 g of the polysiloxane solution of Comparative Example 2 was put into a vial and stored in a refrigerator. The weight-average molecular weight (Mw) was measured by GPC one day after and four days after the beginning of storage. The result was Mw2580 after one day and Mw2800 after four days.

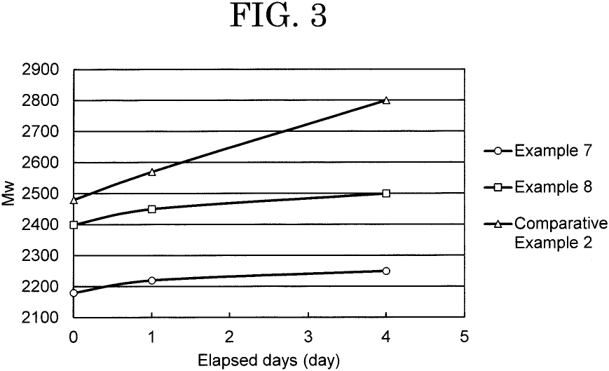

FIG. 3 shows a relationship between a storage time and the weight average molecular weight of the polysiloxane of Examples 7 and 8 and Comparative Example 2. Although the detailed reasons are not clear, it was found that the polysiloxane of Comparative Example 2 increased in molecular weight and had poor storage stability even when stored in a refrigerator. It is presumed that the polysiloxane consisting of p-isomer alone has a small steric hindrance of the HFIP group, and the polycondensation proceeds during storage.

From the above results, it was found that by using the silicon-containing monomer mixture of the present invention in which the content of the first silicon-containing monomer and the content of the second silicon-containing monomer satisfy the above-described predetermined ratio, the polymerizability is good, that is, the polysiloxane of the present invention has a high weight-average molecular weight (Mw) and good storage stability.

### Industrial Applicability

The mixture of the silicon-containing monomer (X) and the silicon-containing monomer (Y) obtained by the present invention can be useful as a modifier for a polymer, a surface-treating agent for an inorganic compound, various coupling agents, and an intermediate raw material for organic synthesis in addition to a raw synthesis material for a polymer resin. In addition, the polysiloxane containing the structural unit (1) and the structural unit (2) and the film obtained therefrom are soluble in an alkaline developer, have patterning performance, and are excellent in heat resistance and transparency, and therefore can be used as a protective film for semiconductors, a flattening material and a microlens material, an insulating protective film for touch panels, a liquid crystal display TFT flattening material, a material for forming a core or a cladding of an optical waveguide, a resist for an electron beam, a multilayer resist intermediate film, an underlayer film, or an anti-reflective film, and the like. Among these applications, when used in an optical system member such as a display or an image sensor, fine particles such as polytetrafluoroethylene, silica, titanium oxide, zirconium oxide, or magnesium fluoride can be mixed and used in any ratio for adjusting the refractive index.

According to an embodiment of the present invention, a polysiloxane that has a fast polymerization reaction rate and good storage stability is provided. Alternatively, a silicon-containing monomer mixture as a raw material of the polysiloxane, a resin composition, a photosensitive resin composition, a cured film, or a patterned cured film containing the polysiloxane is provided. Alternatively, a production method for a resin composition containing the polysiloxane, a photosensitive resin composition, a cured film, or a patterned cured film is provided.

What is claimed is:

1. A silicon-containing monomer mixture comprising:
a first monomer containing silicon represented by a following general formula (X); and
a second monomer containing silicon represented by a following general formula (Y), 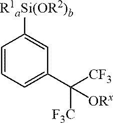 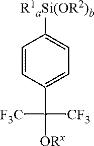
wherein, in the general formula (X), in a case where there are a plurality of R¹, R¹ are independently selected from a group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms and a phenyl group, all of hydrogen atoms of the alkyl group, the alkenyl group or the phenyl group are substituted or are not substituted by fluorine atoms, or a part of the hydrogen atoms of the alkyl group, the alkenyl group or the phenyl group is substituted by fluorine atoms,
in a case where there are a plurality of R², R² are independently a group consisting of a linear alkyl group having 1 to 5 carbon atoms or a branched alkyl group having 3 to 5 carbon atoms, all of hydrogen atoms of the alkyl group are substituted or are not substituted by fluorine atoms, or a part of the hydrogen atoms of the alkyl group is substituted by fluorine atoms,
R^{x} is a hydrogen atom or an acid-labile group, a is an integer of 0 to 2, b is an integer of 1 to 3, a + b = 3,
in the general formula (Y), R¹, R², R^{x}, a and b are defined as the same as in the general formula (X),
A is set to a contained amount of the first monomer containing silicon, B is set to a contained amount of the second monomer containing silicon, and
a following relationship is satisfied in a mole ratio.
$$\text{B} / \left(\text{A} \text{+} \text{B}\right) > 0.04$$

2. A polysiloxane comprising:
a structural unit (1) represented by a following general formula (1); and
a structural unit (2) represented by a following general formula (2), 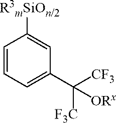 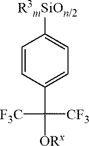
wherein, in the general formula (1), in a case where there are a plurality of R³, R³ are independently selected from a group consisting of a hydrogen atom, a linear alkyl group having 1 to 10 carbon atoms, a branched alkyl group having 3 to 10 carbon atoms, a cycloalkyl group having 3 to 10 carbon atoms, a linear alkenyl group having 2 to 10 carbon atoms, a branched alkenyl group having 3 to 10 carbon atoms, a cycloalkenyl group having 3 to 10 carbon atoms, a phenyl group, hydroxy group, a linear alkoxy group having 1 to 5 carbon atoms, and a branched alkoxy group having 3 to 5 carbon atoms, all of hydrogen atoms of the alkyl group, the alkenyl group, the phenyl group or alkoxy group are substituted or are not substituted by fluorine atoms, or a part of the hydrogen atoms of the alkyl group, the alkenyl group, the phenyl group or alkoxy group is substituted by fluorine atoms,
R^{x} is a hydrogen atom or an acid-labile group,
m is a number of 0 or more and less than 3, n is a number of more than 0 and 3 or less, m + n = 3,
in the general formula (2), R³, R^{x}, m and n are defined the same as in the general formula (1).

3. The polysiloxane according to claim 2,
wherein an existence ratio of the structural unit (1) in the polysiloxane is set to Aa, an existence ratio of the structural unit (2) in the polysiloxane is set to Bb, and
the polysiloxane satisfies a following relationship in a mole ratio.
$$\text{Bb} / \left(\text{Aa} \text{+} \text{Bb}\right) > 0.04$$

4. The polysiloxane according to claim 2 further comprising:
at least one of a third structural unit represented by a following general formula (3) and a fourth structural unit represented by a following general formula (4), 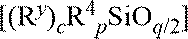 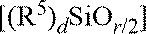
wherein in the general formula (3), R^{y} is a monovalent organic groups having 1 or more and 30 or less carbon atoms containing a functional group selected from a group consisting of an epoxy group, an oxetane group, an acryloyl group, a methacryloyl group or a lactone group,
R⁴ is selected from a group consisting of a hydrogen atom, an alkyl group having 1 or more and 3 or less carbon atoms, a phenyl group, a hydroxy group, an alkoxy group having 1 or more and 5 or less carbon atoms and a fluoroalkyl group having 1 or more and 3 or less carbon atoms,
c is a number of 1 or more and 3 or less, p is a number of 0 or more and less than 3, and q is more than 0 and 3 or less, and c + p + q = 4,
in the general formula (4), R⁵ is a substituent selected from a group consisting of a halogen group, an alkoxy group and a hydroxy group,
d is a number of 0 or more and less than 4, r is a number of more than 0 and 4 or less, and d + r = 4, and
when there are a plurality of R^{y} and R⁴, R^{y} and R⁴ are independently selected from any of the substituents.

5. The polysiloxane according to claim 4, wherein the monovalent organic group R^{y} is a group represented by a following general formulas (2a), (2b), (2c), (3a), or (4a), and 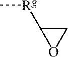 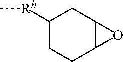 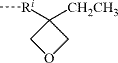 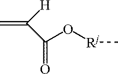 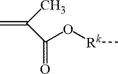
in the general formula (2a), (2b), (2c), (3a), or (4a), R^{g}, R^{h}, Rⁱ, R^{j} and R^{k} each independently represents a linking group or a divalent organic group, and a broken line represents a bond.

6. A resin composition comprising: the polysiloxane according to claim 2; and a solvent.

7. A cured film made of a cured polysiloxane, wherein the polysiloxane according to claim 2 is cured.

8. A cured film made of a cured resin composition, wherein the resin composition according to claim 6 is cured.

9. A production method for a cured film comprising:
a step of applying the polysiloxane according to claim 2 on a substrate and heating the polysiloxane at 100° C. to 350° C.

10. A production method for a cured film comprising:
a step of applying the resin composition according to claim 6 on a substrate and heating the resin composition at 100° C. to 350° C.

11. A photosensitive resin composition comprising:
the polysiloxane according to claim 2 as a component (A);
at least one photosensitizing agent selected from a group consisting of a quinone diazide compound, a photoacid generator, a photobase generator and photo-radical generator as a component (B); and
a solvent as a component (C).

12. A patterned cured film comprising: a pattern structure,
wherein the photosensitive resin composition according to claim 11 is cured.

13. The patterned cured film according to claim 12,
wherein the pattern structure is a concave-convex structure having a pattern size of 500 µm or less.

14. A production method for a patterned cured film comprising:
a step of film formation applying a photosensitive resin composition on a substrate to form a photosensitive resin film;
a step of exposing the photosensitive resin film;
a step of developing the photosensitive resin film after the exposing to form a pattered resin film; and
a step of curing by heating the pattered resin film to convert the pattered resin film to the patterned cured film,
wherein the photosensitive resin composition includes:
the polysiloxane according to claim 2 as a component (A);
at least one photosensitizing agents selected from a group consisting of a quinone diazide compound, a photoacid generator, a photobase generator and photo-radical generator as a component (B); and
a solvent as a component (C).

15. The production method for a patterned cured film according to claim 14, wherein the patterned cured film has a pattern structure of a concave-convex structure having a pattern size of 500 µm or less.

16. The production method for a patterned cured film according to claim 14, wherein a wavelength of a light used in the step of exposing is 10 nm to 600 nm.
